(19) United States
(12) Patent Application Publication
(10) Pub. No.: US 2009/0246357 A1
(43) Pub. Date: Oct. 1, 2009

(54) METHOD OF FORMING CIRCUITS ON CIRCUIT BOARD

(75) Inventors: Shing-Tza Liou, Tayuan (TW); Qiu-Yur Zhang, Shenzhen City (CN); Cheng-Hsien Lin, Tayuan (TW)

Correspondence Address: PCE INDUSTRY, INC.;ATT. Steven Reiss, 288 SOUTH MAYO AVENUE, CITY OF INDUSTRY, CA, 91789, US

(73) Assignees: FUKUI PRECISION COMPONENT (SHENZHEN) CO., LTD., Shenzhen City (CN); FOXCONN ADVANCED TECHNOLOGY INC., Tayuan (TW)

(21) Appl. No.: 12/235,994

(22) Filed: Sep. 23, 2008

(30) Foreign Application Priority Data
Mar. 28, 2008 (CN) 200810300777.4

(51) Int. Cl. H05K 3/12

(52) U.S. Cl. 427/97.3; 29/846

(57) ABSTRACT

A method of forming a circuit on a circuit board includes the steps of: forming a first circuit pattern made of a nano-scale metal oxide material on a surface of an insulating substrate; reducing the nano-scale metal oxide material into a nano-scale deoxidized metal material, thus obtaining a second circuit pattern; and forming an electrically conductive metal layer on the second circuit pattern.

### BACKGROUND

1. Technical Field

The present invention relates generally to methods of manufacturing printed circuit boards and, particularly, to a method of forming circuits to make a circuit board.

2. Description of Related Art

A popular method for forming circuits on a circuit board uses ink jet printing. Ink jet printing is a non-impact dot-matrix printing technology in which droplets of ink are fired from a small aperture directly to a specified position on a medium to create an image.

A conventional ink jet printing method for manufacturing a circuit is disclosed. In the ink jet printing method, a nano-particle ink is fired by an ink jet printer onto a surface of an insulating substrate to form a circuit pattern. Generally, the nano-particle ink is comprised of nano-scale metal particles. However, in the ink jet printing process, the nano-particle ink directly expose in air and the nano-scale metal particles easily oxidize in air, thereby losing their electrical conductivity. Therefore, the nano-scale metal particles are not suitable for use in the nano-ink used to print circuits.

What is needed, therefore, is a method of printing a circuit to make a circuit board which can overcome the above-described problems.

### SUMMARY

An exemplary embodiment of a method of forming a circuit on a circuit board includes the steps of: forming a first circuit pattern made of a nano-scale metal oxide material on a surface of an insulating substrate; reducing the nano-scale metal oxide material into a nano-scale deoxidized metal material, thus obtaining a second circuit pattern; and forming an electrically conductive metal layer on the second circuit pattern.

Advantages and novel features will become more apparent from the following detailed description when taken in conjunction with the accompanying drawings.

### BRIEF DESCRIPTION OF THE DRAWINGS

Many aspects of the present embodiment can be better understood with reference to the following drawings. The components in the drawings are not necessarily drawn to scale, the emphasis instead being placed upon clearly illustrating the principles of the present embodiment. Moreover, in the drawings, like reference numerals designate corresponding parts throughout the several views.

FIG. 1 is a flowchart of a method for forming a circuit on a substrate to make a printed circuit board, according to an exemplary embodiment.

FIG. 2 to FIG. 5 are views showing each step of the method described in FIG. 1.

### DETAILED DESCRIPTION

An embodiment will now be described in detail below and with reference to the drawings.

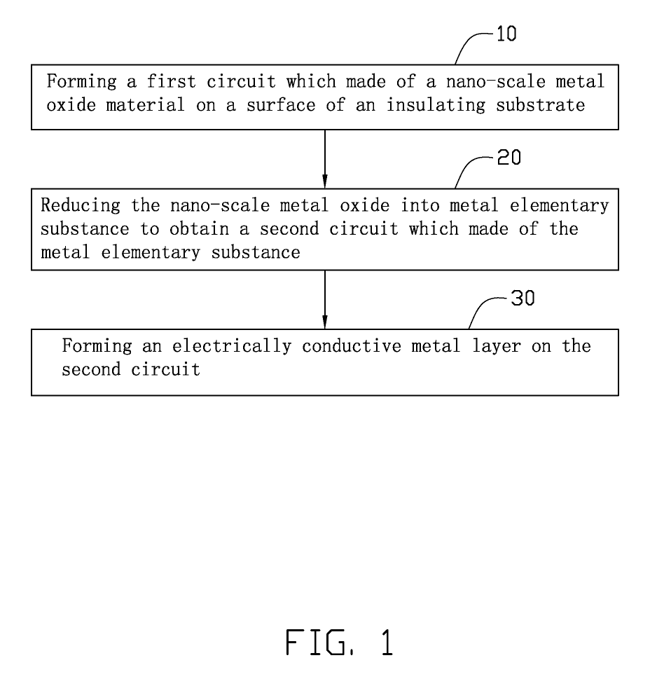

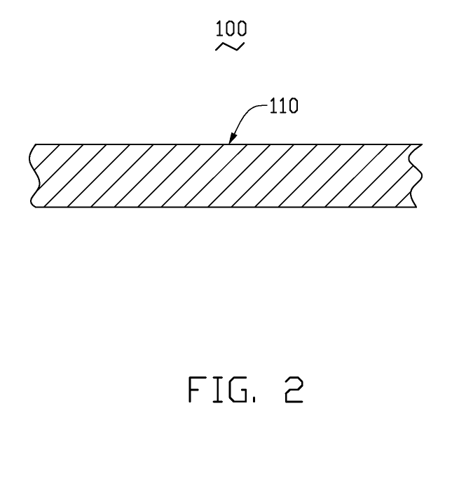

Referring to FIG. 1, an exemplary embodiment of a method of forming a circuit on a circuit board includes: step 10, forming a first circuit pattern made of a nano-scale metal oxide on a surface of an insulating substrate; step 20, reducing the nano-scale metal oxide into a base or deoxidized metal (i.e., non-oxide metal) to obtain a second circuit pattern; step 30, forming an electrically conductive metal layer on the second circuit pattern, thereby obtaining a circuit. Referring to FIG. 2 to FIG. 5, the method of forming a circuit on a circuit board is recited in detail.

In a general first step, referring to FIG. 2, an insulating substrate 100 is provided. The insulating substrate 100 is comprised of a material suitable for making printed circuit board, such as polyimide (PI), polyethylene terephthalate (PET), polyarylene ether nitrile (PEN), etc.

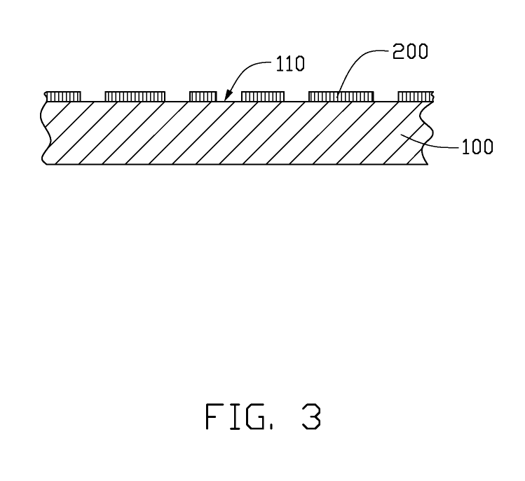

In a general second step, a first circuit pattern 200 is formed on a surface 110 of the insulating substrate 100, as shown in FIG. 3. In order to enable the first circuit pattern 200 to properly bind to the surface 110 of the insulating substrate 100, the surface 110 first undergoes a series of surface treating processes, e.g., a cleaning process, a micro-etching process, to remove pollutants, oil, grease, or other contaminants from the surface 110 of the insulating substrate 100.

The first circuit pattern 200 is formed on the surface 110 using an ink jet printing method. In an ink jet printing process, an ink jet printer is used to form the first circuit pattern 200 using an ink that includes nano-scale metal oxide material. In the process of forming the first circuit pattern 200, a nozzle of the ink jet printer is disposed close to the surface 110, and the ink is fired onto the surface 110 in the desired pattern, i.e., the first circuit pattern 200. The nano-scale metal oxide contained in the ink can be nano-scale aluminum oxide, nano-scale zinc oxide, nano-scale iron oxide, nano-scale magnesium oxide or nano-scale copper oxide. In the present embodiment, the nano-scale metal oxide contained in the ink is nano-scale copper oxide. Compared with the nano-scale metal particles, particles of the nano-scale metal oxide have an excellent dispersive ability, which can prevent aggregation of the nano-scale metal particles. Therefore, the particles of the nano-scale metal oxide are uniformly dispersed and the first circuit pattern 200 with uniform thickness and width is achieved.

The nano-scale metal oxide particles can be prepared using a sol-gel method, a hydrolysis method, a hydrothermal method, a micro-emulsion method, a precipitation method, a solid-phase reaction method, an electrolytic synthesis method or a plasma method. The ink is prepared by dispersing the nano-scale metal oxide material into an organic solvent or a water-soluble medium. In order to improve strength of the adhesive bond between the first circuit pattern 200 and the surface 110, a surface-active agent, dispersant, binder material or macromolecule polymer can be added to the ink to adjust viscosity, surface tension, and stability of the ink. The organic solvent can be a hydrocarbon having eight to twenty-two carbon atoms or aromatic hydrocarbon. The water-soluble medium can be distilled water, a water-soluble organic compound, or mixture of the distilled water and the water-soluble organic compound. The dispersant is resin polymer. The surface-active agent can be a fatty acid ester or a fatty amine. The binder material can be a polyurethane, a polyvinyl alcohol.

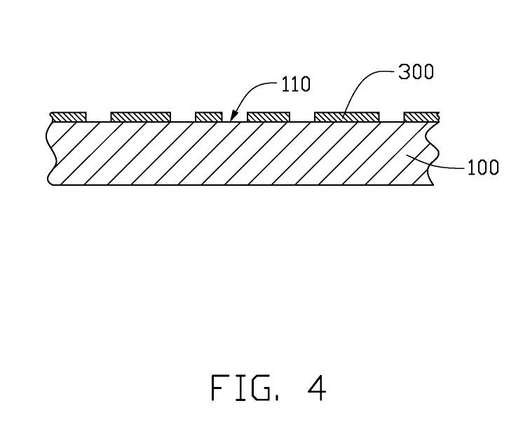

In a general third step, the nano-scale copper oxide particles in the first circuit pattern 200 are reduced into nano-scale copper particles, thus the first circuit pattern 200 is converted or transformed into a second circuit pattern 300 comprised only of nano-scale copper particles, as shown in FIG. 4. The nano-scale copper oxide particles in the first circuit pattern 200 can be reduced to the nano-scale copper particles using a gas or liquid reducing agent. In the present embodiment, the nano-scale copper oxide particles in the first circuit pattern 200 are reduced using hydrogen gas reducing agent. Specifically, a hydrogen filled chamber is provided. The insulating substrate 100 with the first circuit pattern 200 attached thereon is disposed in the chamber. The chamber is heated at a reaction temperature so that the nano-scale copper oxide particles in the first circuit pattern 200 react with the hydrogen. As a result, the nano-scale copper oxide particles in the first circuit pattern 200 are reduced into the nano-scale copper particles. The reaction temperature is generally from about 100 degrees Celsius to about 200 degrees Celsius, and no more than 300 degrees Celsius to avoid burning the insulating substrate 100.

Alternatively, if liquid reducing agent, the reducing solution can be chosen from the group comprising sodium borohydride, potassium borohydride, or dimethyl amino borane. It is understood that any reducing agent capable of reducing the chosen metal oxide can be selected. In addition, the reductive reaction parameters such as temperature, pressure can also be predetermined according to the nano-scale metal oxide particles selected.

Alternatively, the first circuit pattern 200 is made of a nano-scale oxide of a first metal. Then, the nano-scale oxide of the first metal is converted or transformed in to a nano-scale oxide of a second metal through a replacement reaction process, and therefore obtaining an intermediate circuit pattern made of the nano-scale oxide of the second metal. Finally, the intermediate circuit pattern is reduced into the second circuit pattern 300 comprised of a nano-scale deoxidized second metal (i.e., nano-scale nano-oxide metal) through a reducing reaction process.

For example, a molecular formula of the nano-scale metal oxide contained in the first circuit pattern 200 is represented by MₓO_{y}, the desired second circuit pattern 300 should be made of copper, and the metal M is not copper. The MₓO_{y} is combined with a solution to produce a copper oxide through a replacement reaction. In the replacement reaction, a soluble copper salt solution is applied to react with the MₓO_{y}. As a result, the metal M of the MₓO_{y} is transformed to metal M ion to remain suspended in the solution, and the copper ion in the copper salt solution is oxidized to copper oxide (CuO) and forms the second circuit pattern 200. A reaction equation is expressed as: MₓO_{y}+yCu²⁺=xM^{2y/x}+yCuO. The copper oxide is then reduced to deoxidized/non-oxide copper (i.e., the metal copper). Thus, the first circuit pattern 200 which does not contain copper oxide is transformed to the copper based second circuit pattern 300.

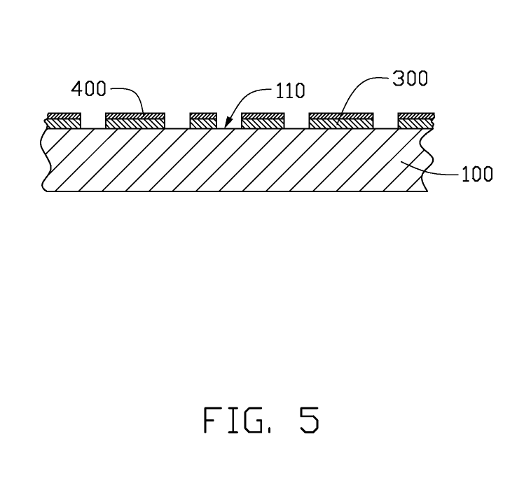

In a general fourth step, a metal layer 400 is plated on the second circuit pattern 300 using an electro-plating method or an electroless-plating method, as shown in FIG. 5. Because the second circuit pattern 300 is transformed from the first circuit pattern 200, which is made of metal oxide (e.g., copper oxide), the non-oxide metal of the second circuit pattern 300 is composed of a number of discontinuous or spaced metal particles (e.g., copper particles) and so may not properly conduct electricity. Therefore, the metal layer 400 is formed on the second circuit pattern 300 to form a properly electrically conductive circuit.

In a plating process, in one aspect, each of the metal particles (e.g., copper particles) in the second circuit pattern 300 is a reaction center, and the metal layer 400 encapsulates each of the metal particles. In another aspect, clearances between adjacent metal particles are filled with the metal layer 400. Therefore, the metal particles of the second circuit pattern 300 are electrically connected to each other by the metal layer 400, through the plating process. In the present embodiment, the metal layer 400 is made of copper, and the second circuit pattern 300 is made of discontinuous or spaced copper particles, so the metal layer 400 electrically connects the copper particles in the second circuit pattern 300.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A method of forming a circuit on a circuit board, the method comprising:
forming a first circuit pattern made of a nano-scale metal oxide material on a surface of an insulating substrate;
reducing the nano-scale metal oxide material into a nano-scale deoxidized metal material, thus obtaining a second circuit pattern; and
forming an electrically conductive metal layer on the second circuit pattern.

2. The method as claimed in claim 1, wherein the first circuit pattern is formed on the surface of the insulating substrate using an inkjet printing method.

3. The method as claimed in claim 2, wherein ink used in the ink jet printing method contains a nano-scale metal oxide material.

4. The method as claimed in claim 3, wherein the nano-scale metal oxide material contained in the ink is selected form the group consisting of nano-scale aluminum oxide, nano-scale zinc oxide, nano-scale iron oxide, nano-scale magnesium oxide and nano-scale copper oxide.

5. The method as claimed in claim 3, wherein the ink comprises at least one of a surface-active agent, a dispersant, a binder material and a polymer.

6. The method as claimed in claim 1, wherein the electrically conductive metal layer is formed on the second circuit pattern using an electro-plating method, an electroless-plating method or a combination thereof.

7. A method of forming a circuit on a circuit board, the method comprising:
forming a first circuit pattern on a surface of an insulating substrate, the circuit pattern made of a nano-scale oxide of a first metal;
converting the nano-scale oxide of the first metal in the first circuit pattern into a nano-scale oxide of a second metal;
reducing the nano-scale oxide of the second metal into a nano-scale deoxidized second metal, thus obtaining a second circuit pattern made of the nano-scale deoxidized metal; and
forming an electrically conductive metal layer on the second circuit pattern.

8. The method as claimed in claim 7, wherein the nano-scale oxide of the first metal is converted into the nano-scale oxide of the second metal through a replacement reaction.

9. The method as claimed in claim 8, wherein in the replacement reaction, a salt solution of the second metal is applied to react with the nano-scale oxide of the first metal, thereby the nano-scale oxide of the first metal being converted into the nano-scale oxide of the second metal.

10. The method as claimed in claim 7, wherein the first circuit pattern is formed on the surface of the insulating substrate using an ink jet printing method.

11. The method as claimed in claim 10, wherein ink used in the ink jet printing method contains the nano-scale oxide of the metal.

12. The method as claimed in claim 11, wherein the nano-scale oxide of the first metal contained in the ink is selected from the group consisting of nano-scale aluminum oxide, nano-scale zinc oxide, nano-scale iron oxide, nano-scale magnesium oxide and nano-scale copper oxide.

13. The method as claimed in claim 10, wherein the ink comprises at least one of a surface-active agent, a dispersant, a binder material and a polymer.

14. The method as claimed in claim 7, wherein the electrically conductive metal layer is formed on the second circuit pattern using an electro-plating method, an electroless-plating method or a combination thereof.
